(19) United States
(12) Patent Application Publication
(10) Pub. No.: US 2009/0236675 A1
(43) Pub. Date: Sep. 24, 2009

(54) SELF-ALIGNED FIELD-EFFECT TRANSISTOR STRUCTURE AND MANUFACTURING METHOD THEREOF

(75) Inventors: Wei-Chang Yang, Taipei City (TW); Tri-Rung Yew, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NATIONAL TSING HUA UNIVERSITY, Hsinchu (TW)

(21) Appl. No.: 12/052,738

(22) Filed: Mar. 21, 2008

(51) Int. Cl. H01L 29/94; H01L 21/336

(52) U.S. Cl. 257/411; 438/301; 257/E21.438; 977/762

(57) ABSTRACT

A self-aligned field-effect transistor (FET) is provided. The self-aligned FET includes a substrate, a dielectric layer, conductive electrodes, and a carbon nanotube. A patterned back-gated conductive electrode is disposed in the substrate. The dielectric layer is disposed on the substrate. The conductive electrodes are disposed on the dielectric layer and function as a source/drain. The patterned source/drain conductive electrodes contain a metal silicide such as cobalt silicide serve as a catalyst for carbon nanotube synthesis. The carbon nanotube is disposed on the dielectric layer to be electrically connected with the source/drain conductive electrodes.

### BACKGROUND OF THE INVENTION

1. Field of the Invention

The present invention generally relates to an integrated circuit device and a manufacturing method thereof, in particular, to a self-aligned field-effect transistor (FET) and a manufacturing method thereof.

2. Description of Related Art

For semiconductor devices of high integration, generally a metal-oxide-semiconductor field-effect transistor (MOSFET) is adopted as a basic logic device, and highly doped mono-Si and poly-Si are used to fabricate electrodes such as sources, drains, and gates. A dielectric layer is an oxide layer resulted from the oxidation of a silicon wafer at a high temperature. To follow the Moore's Law, the line width of a device is continuously decreased, and when a channel length drops to below 45 nm, the current MOSFET may face a technical bottleneck. Thereby, novel device design and material selection become critical.

FIG. 1A is a schematic cross-sectional view of a conventional MOSFET structure. Referring to FIG. 1A, the MOSFET structure 10a includes a substrate 100, a dielectric layer 102, a source/drain 104, and a gate 106. The source/drain 104 is disposed in the substrate 100, the dielectric layer 102 is disposed on the substrate 100, and the gate 106 is disposed on the dielectric layer 102.

Technical documents about the fabrication of an FET with a carbon nanotube have already been issued on relative journals at home and abroad. The carbon nanotube channel is not only used as a basic logic device substituting the MOSFET, but also as a biosensor for sensing gas, glucose, and protein.

FIG. 1B is a schematic cross-sectional view of a carbon nanotube FET already issued on journals at home and abroad. Referring to FIG. 1B, the carbon nanotube FET structure 10b includes a substrate 100, a dielectric layer 102, a gate 106, a catalyst layer 108 (containing Fe, Co, or Ni), a source/drain 114, and a carbon nanotube 112. The gate 106 is disposed in the substrate 100. The dielectric layer 102 is disposed on the substrate 100. The catalyst layer 108 is disposed on the dielectric layer 102. The carbon nanotube is disposed on the dielectric layer, and between the catalyst layer 108. The source/drain 114 is disposed on the catalyst layer 108. Further, in order to simplify the process, the gate 106 in the substrate 100 may be omitted and substituted by a highly B/P-doped silicon substrate to serve as a rear electrode.

In the carbon nanotube FET structure 10b, the carbon nanotube 112 is formed on the dielectric layer 102 and between the catalyst layer 108 through chemical vapor deposition (CVD). After that, the source/drain 114 is defined on the catalyst layer 108 respectively at two ends of the carbon nanotube 112. The ingredients and pretreatment of the catalyst layer 108 may affect the characteristics of the carbon nanotube 112. Therefore, the carbon nanotube 112 may be both metallic and semiconducting. If the carbon nanotube 112 is metallic, the devices may lose the field-effect characteristics thereof and can hardly constitute an FET. In mass production, Fe is not applicable to the current semiconductor industrial process, so the catalyst layer 108 cannot contain Fe. Moreover, the catalyst layer 108 may relatively complicate the mass production (as masks, pretreatment, process parameters, contact between the conductive source/drain and the catalyst layer should be considered). To accelerate the mass production of carbon nanotube FET, a carbon nanotube catalyst must be made of a certain material and have a certain structure compatible with the current semiconductor industrial process.

### SUMMARY OF THE INVENTION

Accordingly, the present invention is directed to a carbon nanotube FET structure, which has an electrode serving as a catalyst and a source/drain simultaneously. The characteristics of the carbon nanotube are controlled through the ingredients, temperature, and pretreatment of the same, such that all the devices on a silicon wafer may constitute a self-aligned carbon nanotube FET.

The present invention provides a transistor structure including a substrate, a dielectric layer, a catalytic source/drain, a gate, and a carbon nanotube. The gate is disposed in the substrate. The dielectric layer is disposed on the substrate. The catalytic source/drain is disposed on the dielectric layer. The carbon nanotube is disposed on the dielectric layer, and electrically connected between the catalytic source/drain. Further, in order to simplify the process, the gate in the substrate may be omitted and substituted by a highly doped silicon substrate to serve as a rear electrode.

In the carbon nanotube FET structure according to an embodiment of the present invention, the substrate is made of, for example, a B-doped or P-doped silicon wafer.

In the carbon nanotube FET structure according to an embodiment of the present invention, the gate in the substrate is made of, for example, a patterned highly P-doped poly-Si, or a highly P-doped silicon wafer to serve as an unpatterned rear electrode.

In the carbon nanotube FET structure according to an embodiment of the present invention, the dielectric layer is made of, for example, SiO₂ or a well-known high dielectric material such as HfO₂, ZrO₂, TaO₂, HfSiO₂, and HfSiNO₂.

In the carbon nanotube FET structure according to an embodiment of the present invention, the dielectric layer is made of, for example, SiO₂, and the thickness of SiO₂ ranges from 1 nm to 500 nm.

In the carbon nanotube FET structure according to an embodiment of the present invention, the catalytic source/drain is made of, for example, a silicide of Co or Ni, such as CoSiₓ or NiSiₓ.

In the carbon nanotube FET structure according to an embodiment of the present invention, the catalytic source/drain is made of, for example, low-resistance CoSi₂.

In a manufacturing method of the carbon nanotube FET structure according to an embodiment of the present invention, the low-resistance CoSi₂ is formed by a multi-layered structure containing Si, Co, Ti at a temperature ranges from 600° C. to 900° C., preferably from 800° C. to 900° C.

In a manufacturing method of the carbon nanotube FET structure according to an embodiment of the present invention, the carbon nanotube is formed by, for example, CVD.

In a manufacturing method of the carbon nanotube FET structure according to an embodiment of the present invention, the carbon nanotube is formed at a temperature ranges from, for example, 600° C. to 900° C., preferably from 800° C. to 900° C., and at a pressure ranges from, for example, 1 Torr to 10 Torr, preferably around 1 Torr. Inlet gases are, for example, C₂H₂ (or, for example, CH₄, C₂H₅OH, C₆H₆CH₃), and H₂ or Ar.

In a manufacturing method of the carbon nanotube FET structure according to an embodiment of the present invention, the flow ratio of C₂H₂ and H₂ ranges from 0.5 to 8, preferably from 3 to 8.

A carbon nanotube FET SEM fabricated according to an embodiment of the present invention and the field-effect characteristics thereof are shown in FIGS. 3 and 4. During the process of fabricating a carbon nanotube FET structure of the present invention, the carbon nanotube is directly formed between the catalytic source/drain containing CoSiₓ for forming the carbon nanotube, thus omitting the step of additionally forming a catalyst layer of the carbon nanotube, so as to simplify the fabrication process. If the position of the source/drain of the FET is first defined through patterning, and then a carbon nanotube is formed by CVD, the purpose of mass production can be achieved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a conventional MOSFET structure.

FIG. 1B is a schematic cross-sectional view of a conventional carbon nanotube FET structure.

FIGS. 2A and 2B are cross-sectional views showing the process of fabricating a self-aligned carbon nanotube FET structure according to an embodiment of the present invention.

FIG. 3 shows an SEM image of a carbon nanotube FET according to an embodiment of the present invention.

FIG. 4 shows characteristics of a carbon nanotube FET according to an embodiment of the present invention.

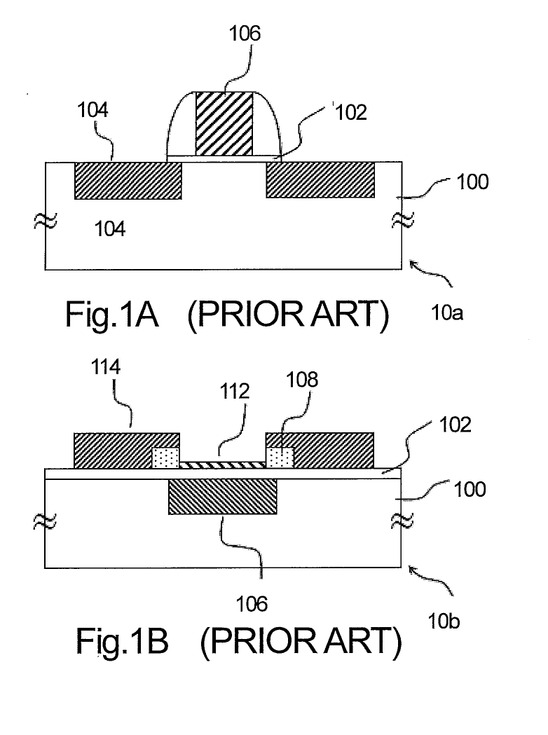

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

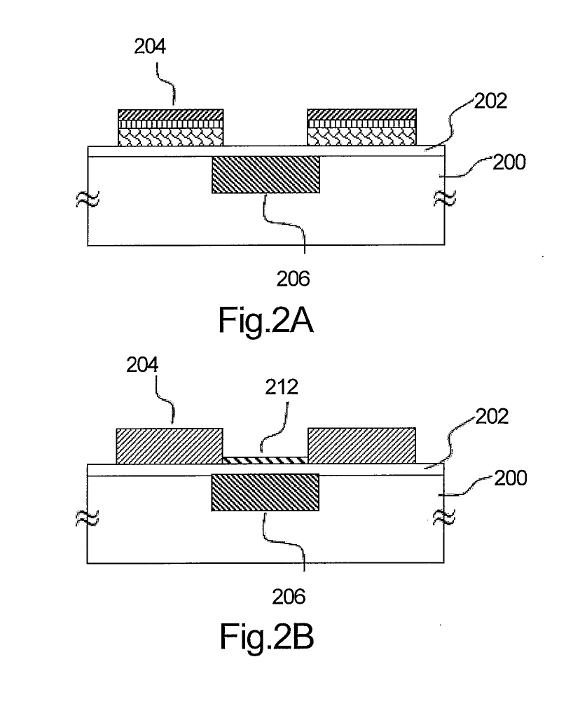

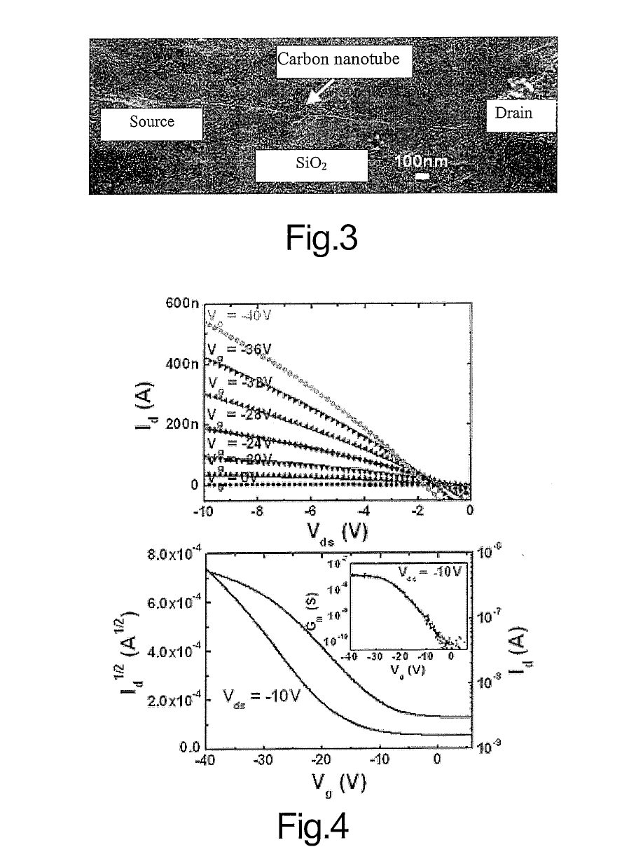

FIGS. 2A and 2B are cross-sectional views showing the process of fabricating a carbon nanotube FET structure according to an embodiment of the present invention. First, a substrate 200 having a gate 206 is provided. The gate 206 is made of, for example, a highly P-doped poly-Si by the following method. First, a highly doped poly-Si is deposited on the substrate 200, and then patterned to form the gate 206 through lithography and etching processes.

Next, referring to FIG. 2A, a dielectric layer 202 is formed on the gate 206. The dielectric layer 202 is made of, for example, SiO₂, and the thickness of SiO₂ ranges from 1 nm to 500 nm, preferably from 5 nm to 500 nm. Then, a catalytic source/drain 204 is formed on the dielectric layer 202. The catalytic source/drain 204 is made of, for example, metal silicide such as CoSi₂ by the following method. First, a poly-Si thin film, a Co thin film, and a Ti thin film are sequentially deposited on the dielectric layer 202, and then patterned to form the source/drain 204 through lithography and etching processes. Finally, the low-resistance CoSi₂ is formed at a temperature ranges from 800° C. to 900° C. The thickness of the formed CoSiₓ may be controlled by adjusting the thicknesses of the Co and Ti thin films. In particular, the thickness of the Co thin film ranges from 0.5 run to 20 nm, preferably from 1 nm to 10 nm, the thickness of the Ti thin film ranges from 1 nm to 20 nm, and the thickness of the formed CoSiₓ ranges from 3 nm to 40 nm.

Again referring to FIG. 2A, the catalytic source/drain 204 is formed on the dielectric layer 202. The catalytic source/drain is made of, for example, CoSiₓ. The catalytic source/drain 204 not only serves as metal electrodes of the carbon nanotube FET, but also as a catalyst for forming the carbon nanotube 212.

The carbon nanotube 212 formed by CVD must be synthesized with a catalyst, so the carbon nanotube 212 may only be formed between the defined catalytic source/drain 204, instead of in a region without the catalytic source/drain on the wafer, i.e., a self-aligned carbon nanotube 212 is formed. Therefore, the purpose of producing the self-aligned carbon nanotube FET in bulk is achieved, and carbon nanotube FETs can be fabricated simultaneously on a wafer.

Referring to FIG. 2B, the carbon nanotube 212 is formed on the dielectric layer 202 and electrically connected between the catalytic source/drain 204. The carbon nanotube 212 is formed by, for example, CVD at a temperature ranges from, for example, 600° C. to 900° C., and at a pressure ranges from 1 Torr to 10 Torr. Inlet gases are, for example, C₂H₂ and H₂ and Ar. In addition, the flow rate of C₂H₂ ranges from, for example, 10 sccm to 80 sccm. The flow ratio of C₂H₂ and H₂ ranges from, for example, 0.5 to 8. In an embodiment, the above process is performed at a temperature of, for example, 900° C., and at a pressure of, for example, 1 Torr, and the flow ratio of C₂H₂ and H₂ is, for example, 6:1.

In this embodiment, CoSiₓ serves as an essential catalyst for forming the carbon nanotube, and meanwhile as an electrode material for forming the source/drain 204. During a high temperature process from 600° C. to 900° C. for forming the carbon nanotube, the CoSiₓ is also formed, and catalyzes the formation of the carbon nanotube 212. In an embodiment, the catalytic source/drain 204 is formed by the low-resistance CoSi₂ at a high temperature (900° C.). Meanwhile, the carbon nanotube 212 is directly disposed between the catalytic source/drain 204, and electrically connected to the low-resistance CoSi₂. Thus, the density, graphitization degree, resistance of the electrode material CoSiₓ of the carbon nanotube 212 can be controlled by adjusting the thicknesses of the Co and Ti thin films as well as the temperature for forming the carbon nanotube 212. Under a more satisfactory process condition, the self-aligned carbon nanotube FET structure 20b provided by the present invention can effectively improve the graphitization degree of the carbon nanotube 212, and assume field-effect characteristics.

In view of the above, for the FET structure 20b of the present invention, the carbon nanotube 212 is directly formed between the catalytic source/drain 204. Thus, the graphitization degree of the carbon nanotube 212 can be improved and the density thereof can be controlled effectively by adjusting the conditions for forming the CoSiₓ (the thicknesses of the Co and Ti thin films, and the process temperature). In addition, the fabricated carbon nanotube FET 20b assumes field-effect characteristics. Therefore, the carbon nanotube FET 20b is effectively fabricated by techniques and materials compatible with the current semiconductor industry in a simplified process of the present invention, so as to achieve the purpose of mass production.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A field-effect transistor (FET) structure, comprising:
a gate layer;
a dielectric layer, disposed on a substrate;
catalytic metal silicides, disposed on the dielectric layer; and
a carbon nanotube, disposed on the dielectric layer, and electrically connected between the two catalytic metal silicides.

2. The FET structure according to claim 1, wherein the substrate is made of a doped low-resistance silicon material.

3. The FET structure according to claim 1, wherein the substrate is made of a high temperature resistant silicide selected from among CoSi₂ and derivatives thereof.

4. The FET structure according to claim 1, wherein the substrate is made of a high temperature resistant metal or compound selected from among W, Ta, TaN, TiN, WN, and derivatives of the above metals and compounds.

5. The FET structure according to claim 1, wherein the dielectric layer is made of SiO₂, or a well-known high dielectric material selected from among HfO₂, ZrO₂, TaO₂, HfSiO₂, HfSiNO₂, and derivatives of the above compounds, and a thickness of the dielectric layer ranges from 1 nm to 500 nm, preferably from 10 nm to 500 nm.

6. The FET structure according to claim 1, wherein the catalytic metal silicides are made of CoSiₓ, or a derivative thereof.

7. The FET structure according to claim 1, wherein the catalytic metal silicides are made of NiSiₓ, or a derivative thereof.

8. A manufacturing method of an FET structure, comprising:
providing a substrate;
forming a dielectric layer on the substrate;
forming catalytic metal silicides on the dielectric layer;
forming a carbon nanotube on the dielectric layer and between the two catalytic metal silicides, wherein the carbon nanotube is electrically connected with the two catalytic metal silicides.

9. The manufacturing method of an FET structure according to claim 8, wherein the substrate is made of a doped low-resistance silicon material.

10. The manufacturing method of an FET structure according to claim 8, wherein the dielectric layer is made of SiO₂ formed by high temperature oxidation or deposition, or a well-known high dielectric material formed by deposition selected from among HfO₂, ZrO₂, TaO₂, HfSiO₂, HfSiNO₂, and derivatives of the above metals and compounds, and a thickness of the dielectric layer ranges from 1 nm to 500 nm, preferably from 10 nm to 500 nm.

11. The manufacturing method of an FET structure according to claim 8, wherein the catalytic metal silicides are made of CoSiₓ, or a derivative thereof.

12. The manufacturing method of an FET structure according to claim 11, wherein a method of forming CoSiₓ comprises making a transition metal and silicon particles diffuse mutually on an interface through high temperature annealing, so as to form a silicide by silicatization.

13. The manufacturing method of an FET structure according to claim 11, wherein a method of forming the catalytic metal silicides comprises physical vapor deposition (PVD), a thickness of a Co thin film ranges from 0.5 nm to 20 nm, preferably from 1 nm to 10 nm, and a thickness of a Ti thin film ranges from 1 nm to 20 nm, such that a thickness of the formed CoSiₓ ranges from 3 nm to 40 mn.

14. The manufacturing method of an FET structure according to claim 8, wherein a method of forming the carbon nanotube comprises chemical vapor deposition (CVD).

15. The manufacturing method of an FET structure according to claim 14, wherein the carbon nanotube is formed at a temperature ranges from 600° C. to 900° C., and at a pressure ranges from 1 Torr to 10 Torr; an inlet gas comprises a reacting gas selected from among C₂H₂, CH₄, C₂H₅OH, and C₆H₆, and a carrier gas selected from among H₂ and Ar.

16. The manufacturing method of an FET structure according to claim 15, wherein a flow rate of C₂H₂ ranges from 10 sccm to 80 sccm, preferably from 60 sccm to 80 sccm.

17. The manufacturing method of an FET structure according to claim 15, wherein a flow rate of H₂ ranges from 1 sccm to 100 sccm, preferably from 10 sccm to 20 sccm.

18. The manufacturing method of an FET structure according to claim 15, wherein a flow rate of Ar ranges from 4 sccm to 400 sccm, preferably from 90 sccm to 180 sccm.

19. The manufacturing method of an FET structure according to claim 15, wherein a flow ratio of C₂H₂ and H₂ ranges from 0.5 to 8, preferably from 3 to 8.
